(19) United States
(12) Patent Application Publication
(10) Pub. No.: US 2002/0153495 A1
(43) Pub. Date: Oct. 24, 2002

(54) Magnetically shielded enclosures for housing charged-particle-beam systems

(75) Inventor: Motofusa Kageyama, Yokohama-shi (JP)

Correspondence Address: KLARQUIST SPARKMAN, LLP, One World Trade Center, Suite 1600, 121 S.W. Salmon Street, Portland, OR, 97204-2988, US

(73) Assignee: Nikon Corporation.

(21) Appl. No.: 10/131,805

(22) Filed: Apr. 22, 2002

(30) Foreign Application Priority Data
Apr. 21, 2001 (JP) 2001-128750

(51) Int. Cl. H01J 37/07

(52) U.S. Cl. 250/492.22; 250/492.2; 250/396 ML

(57) ABSTRACT

Magnetically shielded enclosures are provided that house charged-particle-beam (CPB) systems (e.g., CPB microlithography apparatus) having active-canceler coils. The enclosures have outer walls comprised of anisotropic magnetic materials or of magnetically divided plates. The magnetically divided plates may be made of Permalloy or other similar material. The anisotropic or magnetically divided outer walls may be configured to align the external magnetic field in the direction of the magnetic field produced by the active canceler. Thus, controlling the electrical current in the active-canceler coils to cancel the external magnetic field is simplified, even if the CPB microlithography apparatus has a complex shape or is in an environment with a non-uniform magnetic field.

### FIELD

This disclosure pertains to microlithography (the transfer of a pattern to a sensitive substrate). Microlithography is a key technology used in the fabrication of microelectronic devices such as integrated circuits, displays, and micromachines. Specifically, this disclosure pertains to microlithography using a charged particle beam such as an electron or ion beam. Even more specifically, this disclosure relates to magnetically shielded enclosures, having active-canceler coils, for housing charged-particle-beam (CPB) microlithography apparatus or other CPB systems.

### BACKGROUND

Various types of magnetic shields have been developed in an attempt to alleviate the influence of external static and dynamic magnetic fields on the optical systems of charged-particle-beam (CPB) microlithography apparatus and other CPB systems.

In one conventional approach, the column and vacuum chamber that house the CPB optical system are enclosed in one or multiple layers of a material having a high initial permeability (such as Permalloy). Alternatively, the column and/or vacuum chamber itself may be made of such a material.

An example of an electron-beam microlithography apparatus having conventional magnetic shielding is shown in FIG. 4. Although FIG. 4 shows an electron-beam apparatus, it will be understood that the present invention pertains to any CPB microlithography apparatus. The apparatus of FIG. 4 comprises a column 11 encasing an optical system (not detailed) of the apparatus. The column 11 is contiguous with a vacuum chamber 12. The respective interiors of the column 11 and vacuum chamber 12 are evacuated by a vacuum pump (not shown) connected to a vacuum port 13. Inside the column 11 is an electron source 14 (e.g., electron gun) that produces an electron beam 15. The electron beam 15 is shaped and deflected as required by electron lenses and deflectors (not shown but well understood in the art) of the optical system. Inside the vacuum chamber 12 is a substrate stage 16. Situated externally to the column 11 and vacuum chamber 12 is a magnetic shield 17 made of a material having a high initial permeability.

The column 11 typically defines various openings 18 to allow access inside the column for, e.g., evacuating the column and vacuum chamber 12, making electrical connections to components inside the column (e.g., lenses and deflectors of the optical system), and for moving articles into and out of the column and vacuum chamber. In a system configuration as shown in FIG. 4, corresponding openings 19 also are defined in the magnetic shield 17. Having to provide these openings 19 in the shield 17 results in the shield being divided into multiple segments or portions. These openings 18, 19, as well as any non-magnetic portions of the column 11, define respective “gaps” through which a stray or external magnetic field can enter the column. As used herein, the term “opening” encompasses any of various physical openings as well as any of various gaps.

Dividing the shield 17, having to define openings 19 in it, or otherwise providing gaps in the shield inevitably degrades its shielding properties. Thus, in conventional systems utilizing this approach, it simply is not possible to provide a suitably high level of shielding, especially for a CPB optical system for use in a CPB microlithography apparatus. One approach to improving the magnetic isolation of the charged particle beam inside the column 11 is to surround the entire area in which the CPB microlithography system is placed in magnetic-shielding material, thereby forming a “shielded enclosure.”

An alternative “active” approach to magnetic shielding involves placing coils capable of generating respective magnetic fields in desired directions at a certain distance from the column and vacuum chamber. By selectively adjusting the magnitude and direction of electrical current delivered to individual coils, the coils produce respective magnetic fields that “cancel” the external magnetic field. A magnetic-shielding device employing coils in this manner is referred to as an “active canceler.” An example of a conventional active canceler is shown in FIG. 5, in which the active canceler comprises three pairs of coils 21 and 21′, 22 and 22′, and 23 and 23′, each coil being indicated by a respective circle in the figure. The arrows associated with each circle denote the respective direction of electrical current flowing in the respective coil. Thus, the three pairs of coils 21 and 21′, 22 and 22′, and 23 and 23′ generate three respective magnetic fields oriented in respective mutually perpendicular directions. The individual electrical currents applied to the coils of the active canceler can be adjusted as required to obtain respective magnetic fields of the proper magnitude and direction to cancel the external fields.

Each of these conventional approaches to magnetic shielding suffers from significant limitations. The conventional approach of surrounding the column with a magnetic-shielding material is limited by the need to define openings or gaps in the shielding material or by the need to divide the shielding into multiple portions. This limitation makes it impossible to achieve adequate shielding. Further, if the column is situated in a poor magnetic environment, or if the column is especially sensitive to external magnetic fields, double or triple shielding must be used. Such extensive shielding greatly increases both the mass of the CPB microlithography system and the floor area required to accommodate the system, resulting in substantially higher costs.

Further, although the conventional approach utilizing active cancelers is effective for shielding a CPB microlithography system having a simple shape, such as a cylinder, it is not effective for shielding systems having more complex shapes. Moreover, active cancelers have a limited ability to cancel external magnetic fields that are highly non-uniform. Therefore, if either of these conditions is present, it is extremely difficult to use active cancelers to obtain the desired magnetic-field distribution within the column.

### SUMMARY

In view of the shortcomings of conventional apparatus and methods as summarized above, an object of the present invention is to provide a magnetically shielded enclosure for charged-particle-beam (CPB) microlithography apparatus that utilize active-canceler coils. The enclosures of the present invention can be used for CPB microlithography apparatus that have complex shapes and/or operate in conditions where the external magnetic field is not uniform.

It is noted that “canceling” the external magnetic field does not necessarily mean reducing the magnetic field to zero, but rather connotes reducing the effects of the external magnetic field at specified locations to levels that do not cause any adverse effects to the CPB microlithography apparatus.

According to a first aspect of the invention, an enclosure is provided that has outer walls comprised of an anisotropic magnetic material. The anisotropic outer walls may be configured to align the external magnetic field with the direction of the magnetic field produced by the active canceler. With such a system, controlling the electrical current in the active-canceler coils to cancel the external magnetic field is simplified, even if the CPB microlithography apparatus has a complex shape or is in an environment in which a non-uniform magnetic field is present.

According to a second aspect of the invention, an enclosure is provided that has outer walls comprised of plates that are magnetically divided. These plates may be constructed of Permalloy or other similar material. Like the anisotropic walls discussed above, the magnetically divided plates may be aligned to orient the external magnetic field in the direction of the magnetic field produced by the active canceler.

The foregoing and additional features and advantages of the invention will be more readily apparent from the following detailed description, which proceeds with reference to the accompanying drawings.

### BRIEF DESCRIPTION OF THE DRAWINGS

FIG. 1 (a) is an oblique elevational view of a magnetically shielded enclosure according to a first representative embodiment.

FIG. 1 (b) is a transverse view, along a plane parallel to the active-canceler coil 2b, of the enclosure shown in FIG. 1 (a).

FIG. 2(a) is an oblique elevational view of a magnetically shielded enclosure according to a second representative embodiment.

FIG. 2(b) is a transverse view, along a plane parallel to the active-canceler coil 2b, of the enclosure shown in FIG. 2(a).

FIG. 3 is an elevational section view of an enclosure, such as either of the first and second embodiments, containing a CPB microlithography apparatus.

FIG. 4 is an elevational section of a column and contiguous vacuum chamber including conventional external magnetic shielding.

FIG. 5 is an oblique elevational view of a conventional active canceler.

### DETAILED DESCRIPTION

Various aspects of the invention are described below in the context of representative embodiments, which are not intended to be limiting in any way.

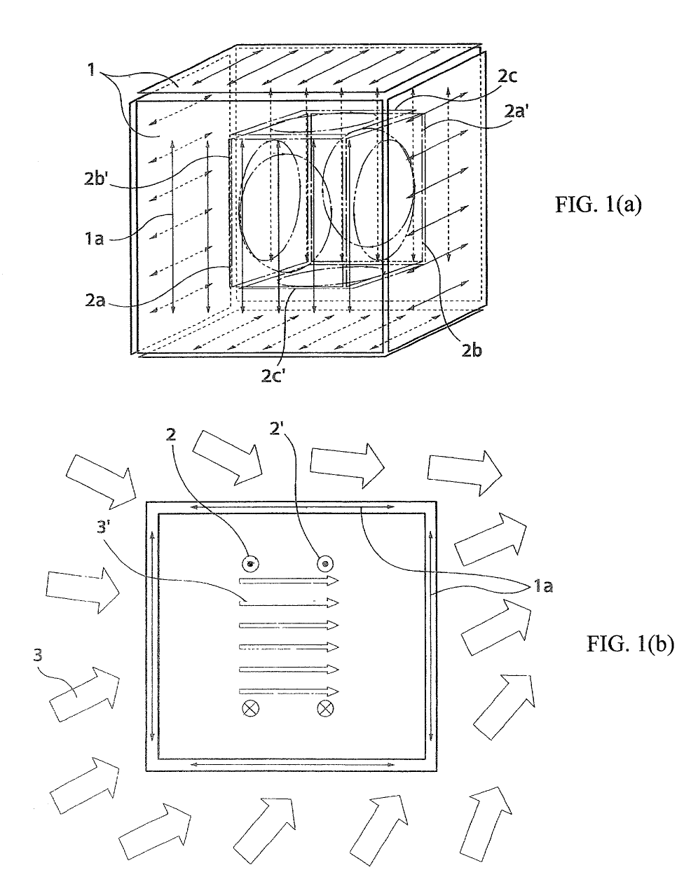

A first representative embodiment of a magnetically shielded enclosure is described with reference to FIGS. 1(a) and 1(b). Three pairs of coils, 2a and 2a′, 2b and 2b′, and 2c and 2c′, comprise an active canceler within the enclosure. The three pairs of coils generate three respective magnetic fields in mutually perpendicular directions. Magnetically shielded outer walls 1 form the enclosure. The outer walls 1 are comprised of an anisotropic material (e.g., grain-oriented silicon-steel plate). An important property of an anisotropic material is that it imparts less resistance to magnetic flux in certain directions than in others. Thus, by properly configuring anisotropic materials within a magnetic field, one can shape the magnetic field by creating pathways of less resistance along which the magnetic field will conform. Accordingly, the anisotropic outer walls 1 of the first representative embodiment are configured to align an external magnetic field in the directions denoted by arrows 1a.

FIG. 1 (b) is a transverse view of the enclosure along a plane parallel to the active-canceler coil 2b shown in FIG. 1 (a). The external magnetic field incident on the enclosure is denoted by arrows 3. The magnetic field within the enclosure and aligned by the anisotropic outer walls is denoted by arrows 3′. If the external magnetic field is aligned by the anisotropic walls so that the field has a direction parallel to the magnetic field created by coils 2 and 2′, only one pair of coils is needed to achieve active cancellation. If desired or as required, each coil 2, 2′ can be energized with the same or with different electrical currents.

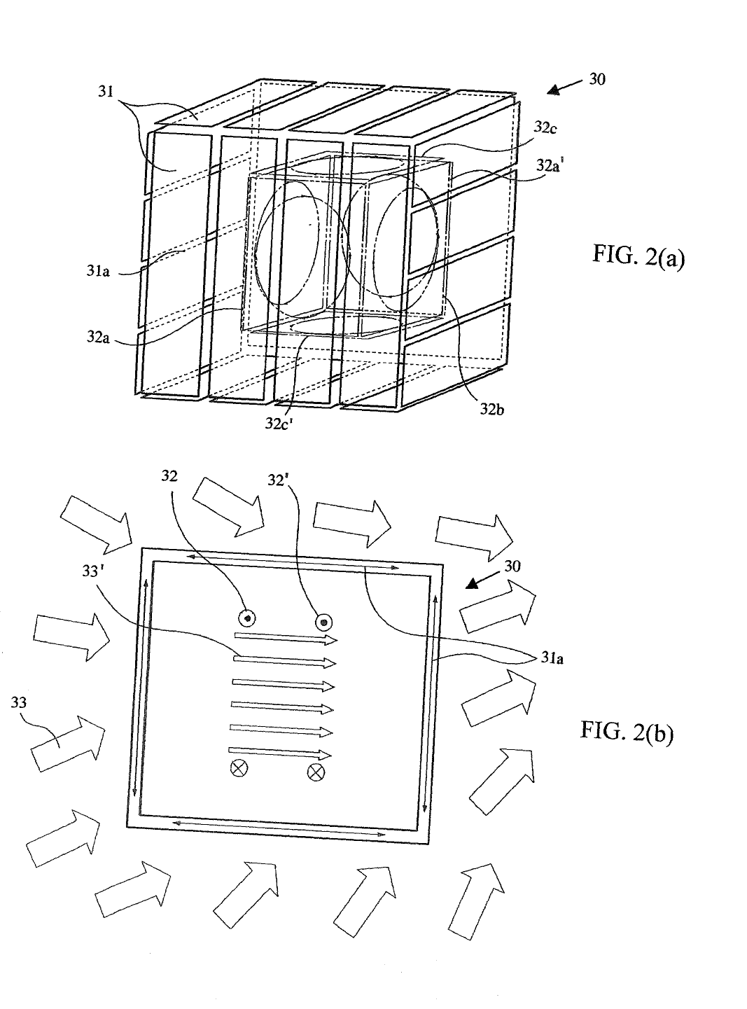

A second representative embodiment of a magnetically shielded enclosure 30 is described with reference to FIGS. 2(a) and 2(b). Three pairs of coils, 3a and 3a′, 3b and 3b′, 3c and 3c′, comprise an active canceler within the enclosure 30. The three pairs of coils generate three respective magnetic fields in mutually perpendicular directions. Magnetically shielded outer walls 31 form the enclosure 30. Each of the outer walls 31 comprises a plurality of magnetic shield plates 31a constructed of Permalloy or other similar material. The shield plates 31a are magnetically partitioned along the outer walls to provide the least resistance to magnetic flux flowing in the directions indicated by the arrows 1a in the anisotropic outer walls in FIG. 1(a).

FIG. 2(b) is a transverse view of the enclosure 30 along a plane parallel to the active-canceler coil 32b shown in FIG. 2(a). The external magnetic field incident on the enclosure 30 is denoted by arrows 33. The magnetic field within the enclosure 30 and aligned by the magnetically shielded outer walls is denoted by arrows 33′. If the external magnetic field is aligned so that the field has a direction parallel to the magnetic field created by coils 32 and 32′, only one pair of coils is needed to achieve active cancellation. If desired or as required, each coil 32, 32′ can be energized with the same or with different electrical currents.

In this embodiment, the gaps between adjacent magnetic shield plates 31a need not be covered with magnetic shield tape or other shielding material. Direct leaks of magnetic flux through these gaps can be prevented if the gaps are made sufficiently small, typically 0.5 mm or smaller. Alternatively, magnetic flux leaks can be prevented by offsetting the positions of these gaps in additional layers of the outer wall.

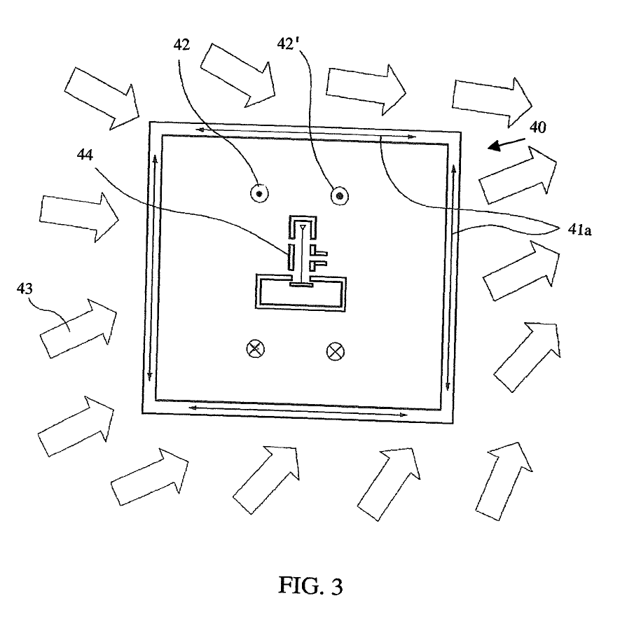

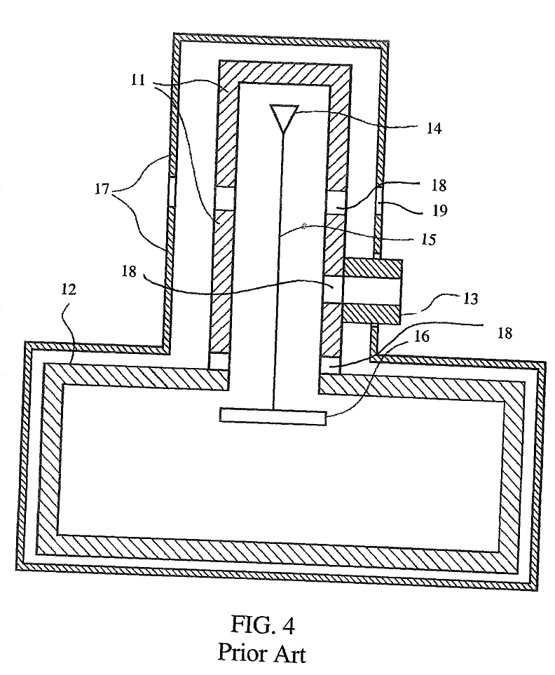

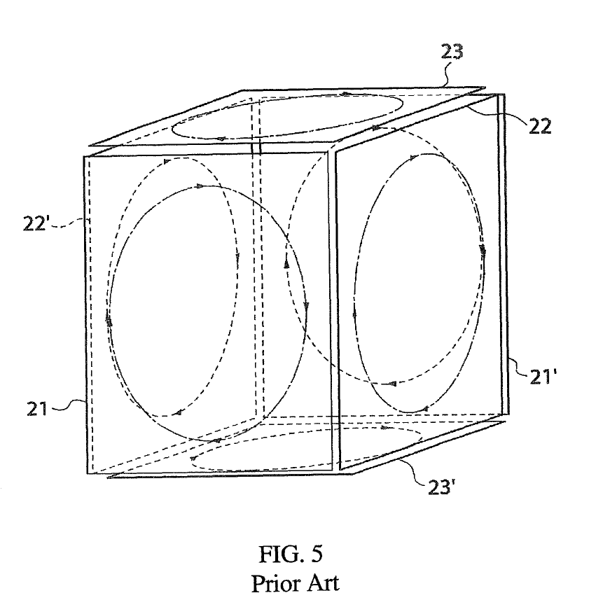

A third representative embodiment of an enclosure 40 is described with reference to FIG. 3. The enclosure 40 contains a CPB microlithography apparatus 44 (or other CPB optical system) and utilizes active cancelers. The CPB microlithography apparatus 44 is installed entirely within the magnetically shielded enclosure 40, allowing the CPB microlithography apparatus to operate in an environment free from external magnetic fields without having to provide magnetic shielding directly around the apparatus as shown in FIG. 4. If desired or as required, each coil 42, 42′ can be energized with the same or with different electrical currents.

As explained above, enclosures according to the present invention allow the magnetic field inside the enclosure to be aligned in a specified direction. This alignment allows the magnetic field inside the enclosure to be effectively canceled by an active canceler even if a CPB microlithography apparatus situated inside the enclosure has a complex shape or is in an environment in which the external magnetic field is not uniform. Hence, the active canceler may be of a simplified design and comprise as few as one pair of coils, resulting in easier control, less weight, and lower costs.

Whereas the invention has been described in connection with multiple representative embodiments, it will be understood that the invention is not limited to those embodiments. On the contrary, the invention is intended to encompass all modifications, alternatives, and equivalents as may be included within the spirit and scope of the invention, as defined by the appended claims.

What is claimed is:

1. A charged-particle-beam (CPB) system, comprising:
a CPB optical system;
an active-canceler coil set situated relative to the CPB optical system, the active-canceler coil set comprising at least one coil pair that is individually electrically energizable to produce a respective magnetic field having a direction and magnitude sufficient for canceling at least a portion of an external magnetic field that otherwise would extend to the CPB optical system; and
a shielded enclosure situated externally relative to the active-canceler coil set, the shielded enclosure comprising at least one outer wall comprised of an anisotropic magnetic material.

2. The system of claim 1, further comprising a column, on which the active-canceler coil set is situated and which contains the CPB optical system.

3. The system of claim 1, wherein the active-canceler coil set comprises at least one coil pair configured to produce a respective magnetic field, situated internally relative to the active-canceler coil set, oriented in at least one prescribed direction.

4. The system of claim 3, wherein the at least one outer wall is configured to align the external magnetic field, extending internally relative to the shielded enclosure, in a direction parallel to the prescribed direction.

5. The system of claim 1, wherein the CPB optical system is of a microlithography apparatus.

6. The system of claim 1, wherein the CPB optical system is enclosed within a second magnetically shielded enclosure directly adjacent to the CPB optical system.

7. A charged-particle-beam (CPB) system, comprising:
a CPB optical system;
an active-canceler coil set situated relative to the CPB optical system, the active-canceler coil set comprising at least one coil pair that is individually electrically energizable to produce a respective magnetic field having a direction and magnitude sufficient for canceling at least a portion of an external magnetic field that otherwise would extend to the CPB optical system; and
a shielded enclosure situated externally relative to the active-canceler coil set, the shielded enclosure comprising at least two magnetic shield plates separated from each other by a gap.

8. The system of claim 7, further comprising a column, on which the active-canceler coil set is situated and which contains the CPB optical system.

9. The system of claim 7, wherein the magnetic shield plates are made of Permalloy.

10. The system of claim 7, wherein the magnetic shield plates are made of a material having a high initial permeability.

11. The system of claim 7, wherein the active-canceler coil set comprises at least one coil pair configured to produce a respective magnetic field, situated internally relative to the active-canceler coil set, oriented in at least one prescribed direction.

12. The system of claim 11, wherein the magnetic shield plates are configured to align the external magnetic field, extending internally relative to the shielded enclosure, in a direction parallel to the prescribed direction.

13. The system of claim 7, wherein the CPB optical system is of a CPB microlithography apparatus.

14. The system of claim 13, wherein the CPB optical system is enclosed within a second magnetically shielded enclosure adjacent the CPB optical system.

15. The system of claim 7, wherein the gap is less than 0.5 mm.

16. The system of claim 7, wherein:
the shielded enclosure comprises an inner layer and an outer layer each comprising multiple respective magnetic shield plates; and
the outer layer is staggered from the inner layer such that a gap in the outer layer is not aligned with a gap in the inner layer.

17. A method for magnetically shielding a charged-particle-beam (CPB) system including an active-canceler coil set used for canceling at least a portion of an external magnetic field by generating a magnetic field in at least one prescribed direction, the method comprising enclosing the CPB system within at least one wall comprised of an anisotropic material, the anisotropic material of the at least one wall being configured to align an external magnetic field in a direction parallel to the prescribed direction.

18. A method for magnetically shielding a charged-particle-beam (CPB) system including an active-canceler coil set used for canceling at least a portion of an external magnetic field by generating a magnetic field in at least one prescribed direction, the method comprising enclosing the CPB system within at least one wall comprised of at least one magnetic plate having a high initial permeability, the at least one magnetic plate of the at least one wall being configured to align an external magnetic field in a direction parallel to the prescribed direction.

19. The method of claim 18, wherein the at least one magnetic plate is made of Permalloy.
